(19) United States
(12) Patent Application Publication
(10) Pub. No.: US 2025/0146128 A1
(43) Pub. Date: May 8, 2025

(54) Area-Selective Hardmask Deposition: Methods and Tools for Advanced Patterning

(71) Applicant: Nederlandse Organisatie voor Toegepast-natuurwetenschappelijk onderzoek TNO, Gravenhage (NL)

(72) Inventors: Alfredo Mameli, Eindhoven (NL); Jie Shen, Veldhoven (NL); Freddy Roozeboom, Waalre (NL)

(21) Appl. No.: 18/764,717

(22) Filed: Jul. 5, 2024

Related U.S. Application Data
(60) Provisional application No. 63/595,877, filed on Nov. 3, 2023.

(51) Int. Cl. C23C 16/04; C23C 16/02; C23C 16/30; C23C 16/40; C23C 16/455

(52) U.S. Cl. CPC C23C 16/04; C23C 16/0245; C23C 16/308; C23C 16/40; C23C 16/45525

(57) ABSTRACT

The present inventive concept relates to area-selective deposition (ASD) area-selective atomic layer deposition (AS-ALD) processes, and applications thereof. Methods of selectively depositing metal oxides and metal oxynitrides, such as TiO₂ and TiON, on nitride (SiN) as a growth area vs. oxide (SiO₂) as a nongrowth area, and applications thereof in, for example, self-aligned block (SAB) patterning and self-aligned multiple patterning (SAMP) processes are described.

### RELATED APPLICATIONS

This application claims priority to U.S. Provisional Patent Application No. 63/595,877, filed on Nov. 3, 2023, the entire content of which is hereby incorporated by reference in its entirety.

### BACKGROUND

The ever-shrinking critical dimensions in semiconductor devices require the use of steadily increasing numbers of masks and complex fabrication processes. By contrast, reducing the number of masks and processing steps is sought-after for managing edge placement errors (EPEs) and material and processing budgets. Complementary bottom-up manufacturing methods (sometimes referred to as scaling boosters) are therefore gaining increasing importance for cutting such Gordian Knot.

Deep UV photolithography using 193 nm light has been highly reliable and economically robust, even when critical device dimensions are at the sub-10 nm scale. Achieving these feature sizes in manufacturing relies on litho-etch-litho-etch (LELE) multi-patterning, wherein more than one exposure step is used in a single patterning layer to produce features with size and pitch that are much smaller than those imaged by a single mask.

However, for critical device dimensions at 5 nm or less, new problems have been encountered with photolithography, including the high cost associated with transitioning from deep UV (DUV) light sources to extreme UV (EUV) 13.5 nm light sources and resists, and those associated with the fundamentals of statistical variability. These problems have led to a push to find new reliable bottom-up methods for patterning. Area-selective deposition is one such bottom-up “chemical patterning” method that holds promise to allow molecular-scale chemical sensitivity and reaction design to augment traditional “top-down” patterning methods.

Fully self-aligned vias represent an example of how bottom-up fabrication methods, such as area-selective deposition (ASD), can bolster top-down manufacturing ones. In short, ASD is employed to alleviate the EPE when landing a metal connect to the functional device layer underneath by providing an additional dielectric layer that prevents interconnects from being too close to each other. Other examples are contact-over-gate structures, bottom-up filling, selective hardmask layers, and etch-stop layers, which have been detailed, for example, in Parsons and Clark (2020) Chem. Mater. 32(12), 4920-4953.

In ASD, bottom-up structures may be deposited by inhibiting heterogeneous surface reactions only on predefined surfaces of a patterned substrate that consists of growth surfaces (GSs, on which deposition is desired) and nongrowth surfaces (NGSs, on which deposition is not desired). Such control is often exerted through selective manipulation of surface functional groups to either allow (on the GS) or inhibit (on the NGS) the deposition chemistry.

Atomic layer deposition (ALD) is a layer-by-layer deposition method that allows for atomic-level thickness control and layer conformality on 3D structures over large substrate areas. In its most simple expression, ALD relies on the cyclic and alternating exposures of a substrate to a precursor and a co-reactant that undergo self-limiting surface reactions. ALD can offer the optimal conditions to control each individual surface (half-)reaction at the atomic level, during the precursor or the co-reactant steps. If sufficiently large differences in thermodynamics or kinetics of surface reactions exist on growth vs. nongrowth surfaces, selective deposition can be naturally obtained, referred to as inherently selective ALD.

Often, the NGS needs to be selectively modified so that thermodynamic or kinetic control can be achieved. An overview can be found, for example, in Mameli and Teplyakov (2023) Acc. Chem. Res. 56(15), 2084-2095.

Area-selective ALD (AS-ALD) processes have been developed, yet the selective deposition of hardmask materials on SiN as GS with respect to SiO₂ as NGS has been an extremely challenging target to achieve. AS-ALD of TIN, TiO₂, and other typical hardmask materials on SiN vs. SiO₂ materials that are ubiquitous in almost every device patterning step, could dramatically expand the processing window of several patterning processes employed in semiconductor manufacturing. In turn, this would allow better control of edge placement errors and reduce the number of mask steps required during device fabrication.

So far, only one example of AS-ALD on SiN vs. SiO₂ has been reported (Xu et al. (2022) J. Vac. Sci. Technol. A 40(1), 012403). This process allows for depositing ˜2.7 nm of Al₂O₃ on SiNₓ vs. SiO₂ using sequential exposures of small molecule inhibitors, i.e., bis-(dimethylamino) dimethylsilane (BDMADMS) and (dimethylamino) trimethylsilane (DMATMS) on blanket SiN and SiO₂ layers, and dimethylaluminum isopropoxide (DMAI) as an Al precursor and H₂O as a co-reactant. While this example represents a milestone in understanding how to chemically differentiate between SiN and SiO₂ surfaces, its applicability in industry may be limited. Selective deposition needs to be achieved on half-processed patterns where SiO₂ and SiN layers coexist on the surface; thus, for industrially relevant processes, such manipulation of a freshly deposited SiN surface is not a viable option.

In that multiple patterning is crucial to enabling continuous downscaling and ever-shrinking critical dimensions in semiconductor devices, stringent overlay requirements have to be mitigated in order to broaden the processing window. This can currently be achieved by advanced patterning technologies such as self-aligned multiple patterning (SAMP) and self-aligned block (SAB) patterning. However, such technologies increase the number of processing steps needed for functional patterning. Accordingly, there remains a need for improved selective deposition schemes that can selectively deposit hardmask materials on, for example SiN vs. SiO₂ are sought that enable more efficient self-aligned patterning fabrication schemes.

### SUMMARY

Aspects of the inventive concept include methods and tools for simplifying patterning technologies by selective deposition of hardmask materials. Methods of the inventive concept include applications of an SAB patterning technology.

Aspects of the methods of the inventive concept enable high selectivity for deposition between SiN and SiO₂ by exploiting differences in surface fluorination, etch-rate, reactivity with aminosilane inhibitors and in the case of halide precursor electrostatic repulsion to further enhance selectivity.

Aspects of the tools of the inventive concept provide a reduced surface to wall ratio and are less prone to process drifts during plasma etching.

Aspects of the methods of the inventive concept and applications thereof provide a reduction in the number of steps required and a pattern-transfer of denser features over conventional SAB methods and applications.

In an aspect of the inventive concept, provided is a method of selectively depositing a metal oxide or metal oxynitride on a substrate, the substrate comprising a surface, the surface comprising: an oxide layer portion comprising hydroxyl groups on SiO₂ and a nitride layer portion, the method comprising: pretreating the surface with a plasma, wherein the plasma removes a native oxide layer on the nitride layer portion; and functionalizing the surface of the substrate with at least one cycle of exposing the surface to an aminosilane small molecule inhibitor, followed by at least one cycle of: exposing the surface to a metal precursor; and exposing the surface to a co-reactant, to provide a metal oxide or metal oxynitride layer selectively deposited on the nitride layer portion of the substrate over the oxide layer portion of the substrate.

In another aspect of the inventive concept, provided is a method of selectively depositing a metal oxide or metal oxynitride on a substrate, the substrate comprising a surface, the surface comprising: an oxide layer portion comprising hydroxyl groups on SiO₂ and a nitride layer portion, the method comprising: pretreating the surface with a plasma, wherein the plasma removes a native oxide layer on the nitride layer portion; and at least one cycle of: functionalizing the surface of the substrate by exposing the surface to an aminosilane small molecule inhibitor; exposing the surface to a metal precursor; and exposing the surface to a co-reactant, to provide a metal oxide or metal oxynitride layer selectively deposited on the nitride layer portion of the substrate over the oxide layer portion of the substrate.

Further aspects of the inventive concept include tools and devices for performing the methods as described herein, patterned layers prepared by the methods as described herein, and semiconductor devices including patterned layers prepared by the methods as described herein.

### BRIEF DESCRIPTION OF THE DRAWINGS

FIG. 1 depicts an artistic representation of a carousel-type reactor with a plurality of zones according to embodiments of the inventive concept.

FIG. 2 depicts a conventional self-aligned block (SAB) patterning process flow.

FIG. 3 depicts an SAB patterning process flow including an ASD hardmask deposition process according to embodiments of the inventive concept.

FIG. 4 depicts a schematic representation of the area-selective ALD processes for thermal TiO₂ and plasma TiON. The native oxide of SiN (panel a) is etched off using a CF₄/N₂ plasma (panel b), followed by a functionalization step using DMATMS (panel c). Alternating exposures of TiCl₄ and H₂O (panel d), or N₂/H₂ plasma (panel f) are employed to achieve ASD of TiO₂ (panel e) and TiON (panel g), respectively.

FIG. 5 depicts XPS spectra of Ti 2p and Si 2p binding energy ranges on both SiN and SiO₂ for different BC cycles of: t-TiO₂ at 100° C. (panels a and e), t-TiO₂ at 200° C. (panels b and f), p-TiON at 200° C. (panels d and h), and ABC cycles for p-TiON at 200°° C. (panels c and g). For t-TiO₂ and p-TiON BC-type recipes at 200° C., similar experiments were performed but without DMATMS pre-functionalization (dashed lines). Logarithmic scale plots are shown in FIG. 6.

FIG. 6 depicts logarithmic scale plots of FIG. 5. XPS spectra of Ti2p and Si2p binding energy ranges on both SiN and SiO₂ for different BC cycles of: t-TiO₂ at 100° C. (panels a and e), t-TiO₂ at 200°° C. (panels b and f), p-TiON at 200° C. (panels d and h) and ABC cycles for p-TiON at 200° C. (panels c and g). For t-TiO₂ and p-TiON BC-type recipes at 200° C., similar experiments were performed but without DMATMS pre-functionalization (dashed lines).

FIG. 7 depicts thickness as a function of number of atmospheric-pressure spatial ALD cycles for thermal TiO₂ (t-TiO₂) at 100° C. (0.72 Å/cycle) and 200° C. (0.53 Å/cycle) and plasma-enhanced TiON (p-TiON) at 200° C. (0.19 Å/cycle). Spectroscopic Ellipsometry was employed to measure thicknesses, and growth per cycle (GPC) values were estimated by linear fitting. All samples were deposited on c-Si.

FIG. 8 (panel a) Collection of tilted-view SEM images for 250 ALD cycles of t-TiO₂ on patterns consisting of SiN and SiO₂ for different CF₄/N₂ etching “cycles” prior to 5 DMATMS “cycles” and the ALD step: 25, 50, 100, and 150. (panel b) Resulting selectivity in terms of coverage as a function of different etching “cycles” (data points are color coded with SEM images). (panel c) Tilted SEM images and selectivity for t-TiO₂ at: 100° C., 190 cycles (top left), 250 cycles +80 CF₄/N₂ back-etching “cycles” (bottom left); 200° C., 190 cycles (top right), 250 cycles +20 CF₄/N₂ back-etching “cycles” (bottom right). Additional results are shown in FIGS. 11 and 12.

FIG. 9. Panel a) depicts a collection of cross-sectional view SEM images for 250 ALD cycles of t-TiO₂ on patterns consisting of SiN and SiO₂ for different CF₄/N₂ etching “cycles” prior to 5 DMATMS “cycles” and the ALD step: 25, 50, 100 and 150. Panel b) shows the resulting selectivity in terms of thickness as a function of different etching “cycles” (data points are color coded with the SEM images).

FIG. 10 depicts a tilted-view SEM overview at different magnifications with selectivity calculated from coverage. TEM overview of the same sample and high magnification of three distinct patterns with two highlighted defects, i.e., TiON particles. High-resolution EDX scan profiles demonstrate the selectivity of the p-TiON process together with atomic percentage profiles along the dashed vertical black line on the overlaid EDX signals.

FIG. 11 depicts a collection of cross-sectional TEM images of diverse patterns at different magnifications from the same sample shown in FIG. 10.

FIG. 12 depicts tilted-view SEM images for 250 ALD cycles of t-TiO₂ with back-etching on patterns consisting of SiN and SiO₂ at a) 100° C. and b) 200° C. The same settings as those in FIG. 8, panel c were applied (deposition cycles and back-etching “cycles”), only the pre-deposition etching step was optimized.

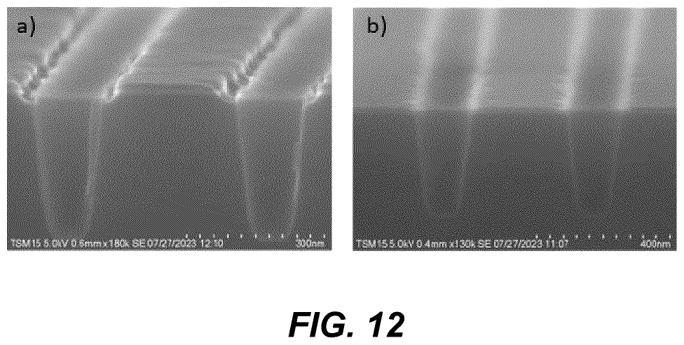

FIG. 13 depicts a collection of SEM tilted view cross-sections for diverse p-TiON deposition recipes: p-TiON was deposited using 50 “cycles” of CF₄/N₂ plasma etching, followed by 5 “cycles” of DMATMS and 380 ABC cycles (DMATMS, TiCl₄, N₂/H₂ plasma) (top row). p-TiON was deposited using 75 “cycles” of CF₄/N₂ plasma etching, followed by 450 BC cycles (TiCl₄, N₂/H₂ plasma) and additional 80 CF₄/N₂ back-etching “cycles” (bottom row).

FIG. 14 depicts XPS spectra of the C 1s region for the same samples shown FIG. 15, panels a and e. No CFₓ features are clearly detected, although minor amounts might still be present at the interfaces between SiO₂ and TiO₂ and SiN and TiO₂.

FIG. 15 depicts XPS surface scans for the F 1s binding energy range for SiO₂ and SiN samples subjected to 100 “cycles” of CF₄/N₂ plasma followed by 5 “cycles” of DMATMS functionalization and: 0 ALD cycles of TiO₂ (pink line on SiO₂, dark blue line on SiN); 100 ALD cycles of t-TiO₂ (red line on SiO₂, blue line on SiN); 250 ALD cycles of t-TiO₂ (orange line on SiO₂, light blue line on SiN). The process temperature was 100° C. for all samples. The main peak centered at 687.0 eV is assigned to fluorine bonded to silicon on a SiO₂ surface (OSi-F), the one at 686.7 eV is assigned to fluorine bonded to silicon on a SiNₓ surface (NSi-F) and/or possible CF species on SiNₓ; the feature at 684.2 eV is attributed to Ti-F.

FIG. 16 depicts XPS spectra of the Ti 2p, Si 2p and F 1s regions for 100 CF₄/N₂ plasma etching “cycles” followed by 5 DMATMS “cycles” and 25, 50, 75, 100 cycles of alternating doses of TDMAT and H₂O on SiN and SiO₂. Ti-F features are visible on both SiO₂ and SiN substrates. Preferential deposition of TiO₂ takes place on the SiN surface, although the difference with SiO₂ is less marked compared to the TiCl₄ case.

### DETAILED DESCRIPTION

The foregoing and other aspects of the present inventive concept will now be described in more detail with respect to other embodiments described herein. It should be appreciated that the inventive concept can be embodied in different forms and should not be construed as limited to the embodiments set forth herein. Rather, these embodiments are provided so that this disclosure will be thorough and complete, and will fully convey the scope of the inventive concept to those skilled in the art.

The terminology used in the description of the inventive concept herein is for the purpose of describing particular embodiments only and is not intended to be limiting of the inventive concept. As used in the description of the inventive concept and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

The term “comprise,” as used herein, in addition to its regular meaning, may also include, and, in some embodiments, may specifically refer to the expressions “consist essentially of” and/or “consist of.” Thus, the expression “comprise” can also refer to, in some embodiments, the specifically listed elements of that which is claimed and does not include further elements, as well as embodiments in which the specifically listed elements of that which is claimed may and/or does encompass further elements, or embodiments in which the specifically listed elements of that which is claimed may encompass further elements that do not materially affect the basic and novel characteristic(s) of that which is claimed. For example, that which is claimed, such as a composition, formulation, method, system, etc. “comprising” listed elements also encompasses, for example, a composition, formulation, method, system, etc. “consisting of,” i.e., wherein that which is claimed does not include further elements, and a composition, formulation, method, system, etc. “consisting essentially of,” i.e., wherein that which is claimed may include further elements that do not materially affect the basic and novel characteristic(s) of that which is claimed.

The term “about” generally refers to a range of numeric values that one of skill in the art would consider equivalent to the recited numeric value or having the same function or result. For example, “about” may refer to a range that is within ±1%, ±2%, ±5%, ±7%, ±10%, ±15%, or even ±20% of the indicated value, depending upon the numeric values that one of skill in the art would consider equivalent to the recited numeric value or having the same function or result. Furthermore, in some embodiments, a numeric value modified by the term “about” may also include a numeric value that is “exactly” the recited numeric value. In addition, any numeric value presented without modification will be appreciated to include numeric values “about” the recited numeric value, as well as include “exactly” the recited numeric value. Similarly, the term “substantially” means largely, but not wholly, the same form, manner or degree and the particular element will have a range of configurations as a person of ordinary skill in the art would consider as having the same function or result. When a particular element is expressed as an approximation by use of the term “substantially,” it will be understood that the particular element forms another embodiment.

The term “substrate,” as used herein, can broadly refer to any layer and/or surface upon which processing is desired. Thus, for example, a native oxide film on the surface of a silicon or silicon nitride substrate may itself be considered a substrate for the purposes of this discussion. Likewise, layers deposited on silicon, silicon nitride, or on other base substrates may likewise be considered substrates in some embodiments. For example, in some embodiments, a multi-layer stack may be formed, and then atomic layer deposition may be performed on the top layer, or a surface of the top layer, of the stack. In such a case, the top layer may be considered the substrate. In general, the layer or layers upon which the chemical precursor is deposited and/or which reacts with the chemical precursor can be considered the substrate layer(s). The material for the substrate may be any that may be appreciated by one of skill in the art in the field of electronics and/or semiconductors.

It will be understood that when an element is referred to as being “on” another element, layer, or substrate, etc., it can be directly on the other element, layer, or substrate, etc., or intervening elements, layers, or substrates, etc. may also be present. In contrast, when an element is referred to as being “directly on” another element, layer, or substrate, etc., there are no intervening elements present.

Unless otherwise defined, all technical and scientific terms used herein have the same meaning as commonly understood by one of ordinary skill in the art to which this inventive concept belongs.

The term atomic layer deposition, or ALD, as used herein, can broadly refer to the level of layer dimensional control in a deposition process, that can be achieved at the angstrom (Å) or sub-angstrom level. Thus, deposition of or growth of a layer through atomic layer deposition, or a cycle thereof, may generally correspond to the size of atoms and/or molecules. The average added layer thickness per cycle of ALD can be less than 1 Å (0.1 nm) per deposition cycle, for example, less than about 0.1 Å, about 0.1 Å, about 0.2 Å, about 0.3 Å, about 0.4 Å, about 0.5 Å, about 0.6 Å, about 0.7 Å, about 0.8 Å, or about 0.9 Å per cycle, or more than 1 Å per cycle, for example, about 1Å, about 1.1 Å, about 1.2 Å, about 1.3 Å, about 1.4 Å, about 1.5 Å, about 1.6 Å, about 1.7 Å, about 1.8 Å, about 2 Å, about 3 Å, about 4 Å, about 5 Å, about 6 Å, about 7 Å, about 8 Å, about 9 Å, about 10 Å (1 nm), about 11 Å, about 12 Å, about 13 Å, about 14 Å, about 15 Å, about 16 Å, about 17 Å, about 18 Å, about 19 Å, or about 20 Å (2 nm) per cycle, or any number between about 0.1-30 Å per deposition cycle. In some embodiments, the average added layer thickness per cycle is between about 0.1-2 Å, about 0.2-2 Å per deposition cycle, about 0.3-2 Å, about 0.4-2 Å per deposition cycle, about 0.5-2 Å per deposition cycle, about 0.6-4 Å per deposition cycle, or about 0.1-4 Å per deposition cycle.

The layer prepared by the methods of the inventive concept may have a thickness of greater than or equal to 1 nm, greater than or equal to 2 nm, greater than or equal to 3 nm, greater than or equal to 4 nm, greater than or equal to 5 nm, greater than or equal to 6 nm, greater than or equal to 7 nm, greater than or equal to 8 nm, greater than or equal to 9 nm, greater than or equal to 10 nm, greater than or equal to 11 nm, greater than or equal to 13 nm, greater than or equal to 14 nm, greater than or equal to 15 nm, greater than or equal to 16 nm, greater than or equal to 18 nm, greater than or equal to 20 nm, in a range of greater than or equal to about 3 nm to about 20 nm, in a range of greater than or equal to about 5 nm to about 20 nm, or in a range of greater than or equal to about 5 nm to about 15 nm.

The choice of chemical precursor or precursors to deposit the metal, metal oxide, metal nitride, or metal oxynitride films according to methods of the inventive concept are not particularly limited, and may be any that may be appreciated by one of skill in the art. In some embodiments, the chemical precursor may include, for example, silicon (Si), titanium (Ti), hafnium (Hf), tantalum (Ta), tin (Sn), molybdenum (Mo), or aluminum (Al). In some embodiments, the chemical precursor includes titanium (Ti), for example, TiCl₄, titanium tetraisopropoxide (TTIP), or tetrakis (dimethylamino) titanium (TDMAT). In some embodiments, the chemical precursor may be a metal halide, for example, SiCl₄, Si₂Cl₆, SiH₂Cl₂, AlCl₃, Al₂Cl₆, FeCl₃, HfCl₄, MoO₂Cl₂, MoF₆, MoCl₅, TaF₅, TaCl₅, Tal₅, WF₆, WCl₆, or ZrCl₄. In some embodiments, the chemical precursor may be TiCl₄. In some embodiments, the chemical precursor may be a silane, e.g., a trihalo-alkysilane, such as but not limited to trichloro (octadecyl) silane, a trimethoxy-alkylsilane or a trimethoxy-aminosilane, such as 3-aminopropyltrimethoxysilane. Similarly, the deposition process is not particularly limited. In some embodiments, the deposition may be a thermal deposition process. In some embodiments, the deposition may be or include a plasma deposition process.

In addition, the co-reactant, or co-reactants, to deposit the metal, metal oxide, metal nitride, metal oxynitride, metal oxycarbide, metal carbonitride, metal carbide, metal sulfide, or metal oxysulfide, or metal (oxy) selenide films according to methods of the inventive concept are not particularly limited, and may be any that may be appreciated by one of skill in the art, for example, H₂O, H₂O₂/H₂O mixtures, O₂, O₃, NH₃, or N₂H₄, or H₂S, or H₂Se, or a hydrocarbon, e.g., CH₄, or a halogenated hydrocarbon, e.g., CHX₃, CH₂X₂, etc. In some embodiments, wherein the deposition is a thermal deposition process, the co-reactant may be H₂O, such as in thermal titanium oxide (t-TiO₂) deposition. In some embodiments, wherein the deposition is a plasma deposition process, the co-reactant may include a gas, for example, N₂, H₂, Ar, O₂, or H₂S, or H₂Se or a mixture of gases, for example, N₂/H₂, H₂/Ar, or N₂/Ar. In some embodiments, the co-reactant may be a N₂/H₂ plasma, such as in plasma titanium oxynitride (p-TiON) deposition. In some embodiments, the plasma deposition may include an NH₃ plasma.

The number of ALD or deposition cycles performed in the methods of the present inventive concept is not particularly limited, and may be any number of cycles that would be appreciated by one of skill in the art. For example, the number of deposition cycles in the process may be between 1 and about 1,000 cycles. In some embodiments, the number of deposition cycles may be between about 1-600 cycles, for example, 1 cycle, about 5 cycles, about 10 cycles, about 20 cycles, about 30 cycles, about 40 cycles, about 50 cycles, about 60 cycles, about 70 cycles, about 80 cycles about 100 cycles, about 150 cycles, about 200 cycles, about 250 cycles, about 300 cycles, about 350 cycles, about 400 cycles, about 450 cycles, about 500 cycles, about 550 cycles, or about 600 cycles, or any number of deposition cycles between and including 1 deposition cycle and about 1,000 deposition cycles. Each deposition cycle may include exposing the substrate to alternating pulses/doses of a chemical precursor and a co-reactant. In some embodiments, the deposition cycle may include exposing the substrate to a pulse/dose, or more than one pulse/dose, for example, 2, 3, 4, 5, 6 pulses/doses, etc. of a chemical precursor, and a pulse/dose, or more than one pulse/dose, for example, 2, 3, 4, 5, 6 pulses/doses, etc. of a co-reactant. Prior to the deposition cycle(s), the surface on which deposition is to take place may be: precleaned, for example, with a plasma/plasma etching step, such as exposure to, or multiple exposures/“cycles” to a CF₄/N₂ plasma, to remove, for example, a native oxide film that may be present on the surface; and/or functionalized, for example, through exposure to, or multiple exposures/“cycles” to a small molecule inhibitor (SMI), for example, an aminosilane, such as bis (N,N-dimethylamino) dimethylsilane (BDMADMS) or (N,N-dimethylamino) trimethysilane (DMATMS). In some embodiments, the aminosilane/SMI may be hexamethyldisilazane (HMDS) or a silatrane, e.g., methylsilatrane, or related compounds. In some embodiments, the SMI may be DMATMS. In some embodiments, functionalization of the surface may selectively passivate remaining exposed hydroxyl groups on the nongrowth surface of the substrate, for example, an oxide layer, such as an SiO₂ layer or portion of a substrate, thus forming an effective inhibition layer for subsequent ALD. Accordingly, any compound/SMI capable of selectively passivating remaining exposed hydroxyl groups on the nongrowth surface of the substrate may be used/envisioned without departing from the scope of the inventive concept.

Accordingly, in some embodiments, a substrate, on which deposition is to take place, may be: precleaned, for example, with a plasma etching step; functionalized, for example, by exposure to an SMI; and followed by at least one deposition cycle including exposure to a precursor and a co-reactant, to provide a layer selectively deposited on a GS vs. an NGS.

In other embodiments, the deposition cycle may include exposure of a surface on which deposition of a film/layer is to take place, for example a surface of a substrate, to an SMI, followed by exposure of the surface to a precursor, and exposure of the surface to a co-reactant. Accordingly, the substrate, on which deposition is to take place, may be precleaned, followed by at least one deposition cycle including: functionalizing the surface, for example, by exposure to an SMI; exposing the surface to a precursor; and exposing the surface to a co-reactant, to provide a layer selectively deposited on a GS vs. an NGS.

In some embodiments, the methods of the inventive concept may include a back-etching step with, for example, exposure to a plasma after the at least one deposition cycle(s). In some embodiments, the chemistry of the back-etching plasma is the same plasma employed for pre-deposition etching/cleaning to limit cross-contamination issues. For example, the precleaning/pre-deposition plasma and the back-etching plasma may both be a mixture, for example, a CF₄/N₂ plasma, but is not limited thereto. In some embodiments, the mixture may include, CF₄, CHF₃, and/or CₓH_{y}F_{z} with H₂, O₂, N₂, and/or Ar. In some embodiments, the back-etching plasma may include Cl₂, and/or mixtures thereof with H₂, N₂, O₂, and/or Ar. In some embodiments, the back-etching plasma may include NH₃, and/or mixtures thereof with N₂ and/or H₂. The exposure of the layer or layers deposited on a substrate to the back-etching plasma may include, for example, a single exposure, or may include multiple exposures/“cycles” to the back-etching plasma.

The exposure of the substrate to a plasma to preclean the substrate prior to deposition, and the exposure of the substrate to a plasma to back-etch following deposition, may include a single plasma exposure or “cycle” on a rotating workpiece/rotary spatial ALD reactor, as opposed to an ALD deposition cycle, or may include multiple plasma exposures/“cycles” on the ALD reactor. The number of plasma exposures/“cycles” prior to deposition and/or postdeposition back-etching is not particularly limited. This number may be anywhere from 1 to about 100 exposures/“cycles.” In some embodiments, the number of pre-deposition plasma exposures/“cycles” may be between about and including 50 to about 100 exposures/“cycles of precleaning plasma prior to ALD. In some embodiments, the number of post-deposition back-etching plasma exposures/“cycles” may be about and including 20 to about 80 exposures/“cycles” of back-etching plasma following ALD.

In some embodiments, when functionalizing the substrate on which deposition is to take place by exposure to an aminosilane SMI prior to ALD, the exposure of the substrate to the functionalizing SMI may include a single exposure or “cycle” on a rotating workpiece/rotary spatial ALD reactor, or exposure of the substrate to the functionalizing SMI may include multiple plasma exposures/“cycles” on the ALD reactor. For example, the number may be anywhere from 1 to about 10 exposures/“cycles,” for example, the number of exposures/“cycles” may be about 5 exposures/“cycles” when functionalizing the substrate prior to ALD.

The temperature and/or pressure at which the methods of the present inventive concept are performed are not particularly limited. Nevertheless, in some embodiments, the temperature at which the ALD methods are performed between and including about 100° C. and about 300° C. In some embodiments, the temperature is between and including about 100° C. and about 250° C. In some embodiments, the temperature is between and including about 100° C. and about 200° C. In some embodiments, the pressure at which the ALD methods are performed at atmospheric or ambient pressures.

The present inventive concept overcomes the limitations and disadvantages of prior techniques. The inventive concept provides ALD techniques, which enable the selective deposition of metals, metal oxides and metal oxynitrides on a surface or substrate. According to embodiments of the present inventive concept, selective deposition may refer to deposition of, for example, a material, such as a metal or a material including a metal, on a first portion of a surface or substrate, such as a GS, with no detectable deposition, with minimal deposition, or with significantly less or reduced deposition, of the material on a second portion of the substrate or surface, such as an NGS. The first and second portions of the surface or substrate may be of differing materials or composition. For example, in some embodiments, the first portion of the surface may be a nitride layer, for example, a silicon nitride (SiN) layer, a carbon-doped silicon nitride (silicon carbon nitride, SiCN) layer, or a metal nitride layer such as HIN, TiN, and/or ZrN, i.e., exemplary nitrides of group-IV metals/elements, or SnN, or nitride layers that may include germanium (Ge) or lead (Pb), and the second portion of the surface may be an oxide layer including hydroxyl groups from SiO₂, such as a silicon oxide (SiO₂) layer, a carbon-doped silicon oxide (C: SiO₂) layer, or a silicon carbide (SiC) layer. In some embodiments, the first portion of the surface may be crystalline silicon (c-Si).

“Selective deposition,” “area selective deposition” (ASD), and “area selective atomic layer deposition” (AS-ALD) refer to processes that lead to deposition of materials on only desired area of, for example, a patterned substrate. The patterned substrate may include areas or portions, and deposition is desired on one area or portion but not the other. Accordingly, selective deposition may include deposition of, for example, a material, such as a metal or a material including a metal, on a first portion (GS) of a surface or substrate, with no deposition, with minimal deposition, or with significantly less or reduced deposition, of the material on a second portion (NGS) of the substrate or surface. The first and second portions/areas of the surface or substrate may be of differing materials or composition.

In some embodiments, the selectivity of deposition may be defined, for example, as discussed in Gladfelter (1993) Chem. Mater. 5 (10), 1372-1388, and as set forth by Equation (1):

$$S = \frac{{X}_{GS} - {X}_{NGS}}{{X}_{GS} + {X}_{NGS}} \qquad ( 1 )$$

wherein X_{GS} and X_{NGS} are measurements of the amount of material deposited (thickness or area coverage) on the growth surface (GS) and on the nongrowth surface (NGS). S may have a value between 0 and 1, wherein S=0 is indicative of no selectivity of deposition on the GS and the NGS, and wherein S=1 is indicative of complete (100%) selectivity of deposition on the GS and the NGS. In some embodiments, the methods of the inventive concept may have a selectivity of deposition S of ≥0.80, ≥0.85, ≥0.88, ≥0.90, ≥0.91, ≥0.92, ≥0.93, ≥0.94, ≥0.95, ≥0.96, ≥0.97, ≥0.98, or ≥0.99, or even S=1.00, wherein no detectible deposition takes place/is observed on the NGS.

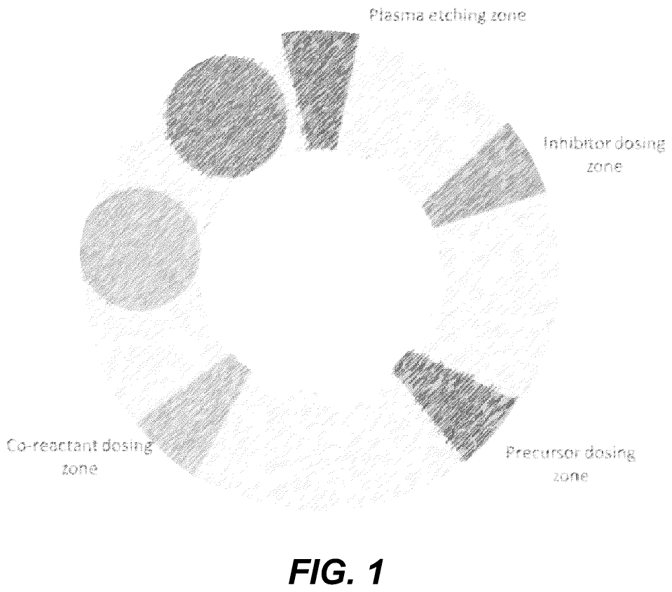

In some embodiments, tools of the inventive concept include a carousel-type reactor for performing pre-treatments and deposition steps without exposing the workpiece to a different atmosphere. In some embodiments, the carousel-type reactor may contain a plurality of plasma etching zone(s), inhibitor, precursor, and co-reactant etching zones. FIG. 1 depicts an exemplary artistic representation of a carousel-type reactor with a plurality of zones.

A semiconductor device may be formed on the workpiece. The semiconductor device may comprise SiN and SiO₂ patterned areas/layers, for example, including an SiN core and SiO₂ spacers.

The plasma zone is equipped to perform plasma chemistries that enable etching of SiO₂ (and SiN) e.g. (CF₄, H₂, CF₄ H₂ mixtures, and general fluorocarbon chemistries CₓH_{y}F_{z}) to reveal fresh SiN surfaces and thus provide enough chemical contrast for carrying out selective deposition processes. Alternatively, other etching methods such as thermal or plasma atomic layer etching may be used for the same purpose. The dosing from the multitude of zones is computer programmable such that N cycles of plasma etching can be performed with a rotation speed comprised between 0.5 and 200 RPM. Upon plasma etching in particular a partially fluorinated SiN and SiO₂ surface is formed. Silane-based inhibitors such as (N,N-dimethylamino) trimethylsilane (DMATMS) can then be dosed with appropriate rotation speed between 0.5 and 200 RPM. In some embodiments, the total dose (vapor pressure x exposure time) is adjusted so that only one exposure is needed, and the atomic layer deposition process can be performed immediately thereafter. Alternatively, multiple rotations/“cycles” of the workpiece are performed to functionalize the surface before the chemistry is switched to deposition. DMATMS selectively passivates the remaining exposed hydroxyl on the partially fluorinated SiO₂ thus forming an effective inhibition layer for subsequent ALD. TiO₂ TiN, TiOₓN_{y}, TiC, HfO₂, HfN, HfON, Ta₂O₅, TaN, TaOₓN_{y} SiN, Al₂O₃ can be selectively deposited on the partially fluorinated SiN in presence of fluorinated and silylated SiO₂. Amino-based precursors and halide-based precursors (halides may be used to enhance the electrostatic repulsions) may be employed as ALD precursors. H₂O, O₃ H₂O₂ or oxidizing plasma chemistries (CO₂, CO, O₂, H₂O) are employed to selectively grow oxides, while NH₃, N₂H₄ or N₂ H₂ or N₂/H₂ mixtures are employed to selectively deposit nitrides and/or oxynitrides materials thermally or by plasma. The silane-based inhibitor may be applied as a pretreatment step, prior to and not as part of the ALD cycle (BC-type cycles for ALD), in which only chemical precursor and co-reactant dosing are included in the ALD step, or the silane-based inhibitor may be applied as part of the ALD cycle (ABC-type cycles for ALD), wherein inhibitor, chemical precursor, and co-reactant dosing are included in the ALD step. In cases of plasma-based deposition processes, the inhibitor may be re-applied after every m (with m>1) cycle(s), for example, every 2, 3, 4, 5, etc. cycles, in order to refresh the inhibition layer, as opposed to as a pretreatment step with BC-type cycles for ALD, with every cycle (m=1) with ABC-type cycles for ALD.

One or multiple plasma (or thermal) etching zones can be employed for correction steps in cases where the selectivity is limited. Unwanted material can then be removed by selected etch-back chemistries. In some embodiments, the chemistry of the back-etching is the same as that employed for pre-deposition etching in order to limit cross-contamination issues.

Alternatively, in some embodiments, a cluster tool is employed with separate chambers dedicated to etching and deposition. A timely and under inert atmosphere transfer is needed in order to prevent surface oxidation of the freshly etched SiN pattern.

Current SAB approaches make use of and require several pattering steps and spin-on coating steps for patterning.

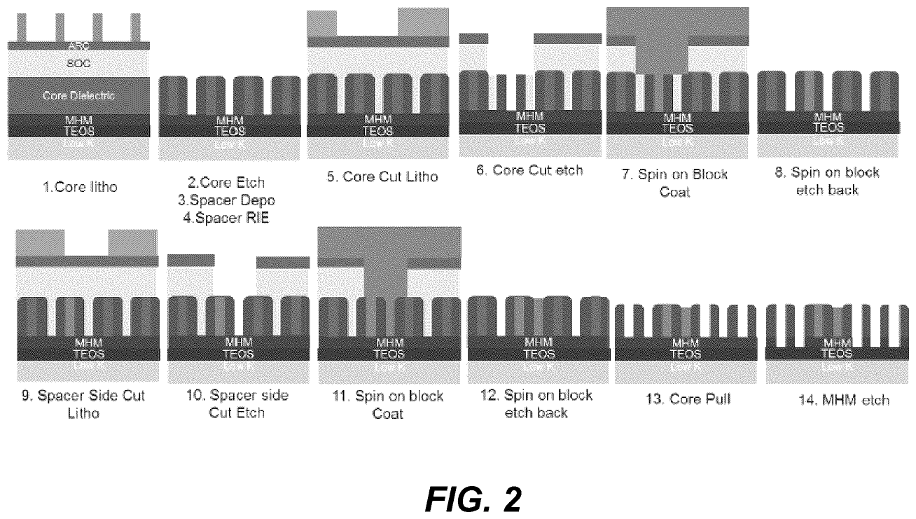

A standard SAB process flow may include steps of: (1) core lithography; (2) core etch; (3) spacer deposition; (4) spacer RIE; (5) core cut lithography; (6) core cut etch; (7) spin on block coating; (8) spin on block etch back; (9) spacer side cut lithography; (10) spacer side cut etch; (11) spin on block coat; (12) spin on block etch back; (13) core pull; and (14) metal hardmask etch, for example, as depicted in FIG. 2.

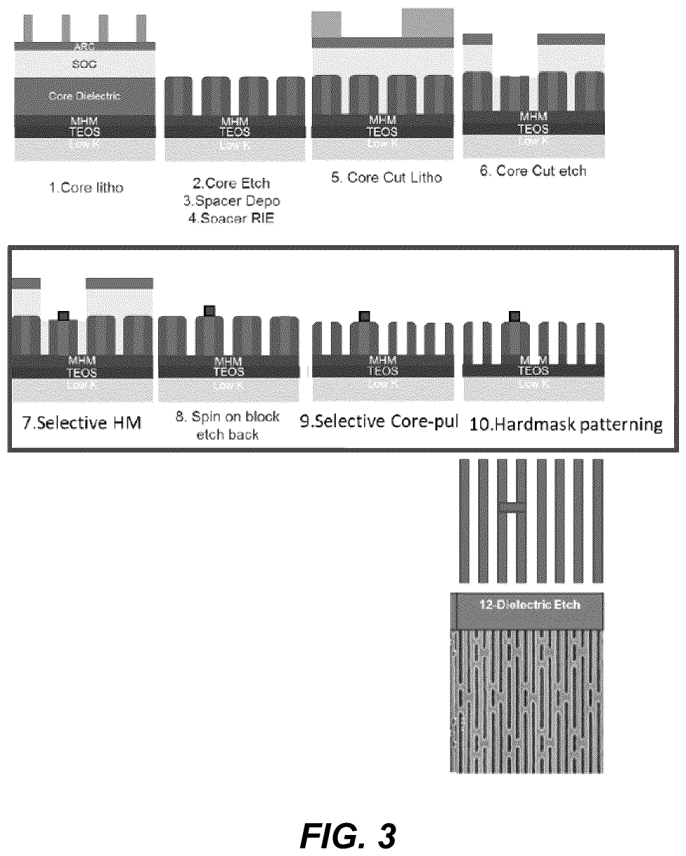

In contrast, the SAB with an ASD hardmask deposition according to embodiments of the inventive concept, for example, as depicted in FIG. 3, can reduce the number of steps in the process flow and transfer patterns with features of greater density. The process flow according to embodiments of the inventive concept may include the steps of: (1) core lithography; (2) core etch; (3) spacer deposition; (4) spacer RIE; (5) core cut lithography; and (6) core cut etch as in a standard SAB process, followed by: (7) selective hardmask deposition; (8) spin on block etch back; (9) selective core pull; and (10) hardmask patterning.

The SAB process flow of the inventive concept, including an ASD hardmask deposition, reduces the number of steps required for pattern-transferring, and permits the transfer of denser features in the SAB process. It further enables selective deposition on SiN vs. SiO₂ with high-throughput, and provides an option for back-etching, all within the same tool which can be critical for such a challenging selective deposition process.

Chemistries that provide enough deposition selectivity between SiN and SiO₂ are not obvious and very few examples have been provided in the literature. Pre-treatments are crucial for enabling such selectivity between SiN and SiO₂. The carousel-type reactor design of the inventive concept has several advantages for this purpose: short timelapse between SiN surface revealing step and inhibitor dose. This is crucial to limit SiN surface oxidation and hence degradation of selectivity. The preferred use of halide-based precursors enables low-temperature and low-carbon content selective hardmask materials to be deposited and enhanced the attainable selectivity by electrostatic repulsion with the partially fluorinated surfaces.

Having described various aspects of the present inventive concept, the same will be explained in further detail in the following examples, which are included herein for illustration purposes only, and which are not intended to be limiting to the inventive concept.

### EXAMPLES

Herein, an industrially compatible route for AS-ALD of both TiO₂ and TiON on SiN vs. SiO₂ using both thermal and plasma processes is demonstrated. The process makes use of CF₄ plasma chemistry to remove the native oxide(s) from SiN surfaces, followed by a DMATMS functionalization step. AS-ALD of thermal TiO₂ (t-TiO₂) and plasma TiON (p-TiON), using titanium tetrachloride (TiCl₄) as the Ti-precursor, was demonstrated by scanning and transmission electron microscopy (SEM and TEM, respectively). Virtually perfect selectivity for t-TiO₂ is demonstrated at both 100 and 200° C. in combination with plasma back-etching correction steps, leading to ˜8 and ˜7 nm-thick selective deposition. For p-TiON, high selectivity was achieved for ˜5 nm-thick selective deposition. By coincidence, the same process was found to be selective also on Si vs. SiO₂, thus revealing a broader scope. The effect of several process parameters (deposition temperature, precursor chemistry, recipe strategies) has also been investigated. Lastly, considerations on the underlying surface chemistry enabling the selectivity of these processes are drawn on the basis of these results.

### METHODS

ALD Processes. Depositions were carried out in a home-built rotary spatial ALD reactor. The reactor consists of a rotating substrate holder that can accommodate 150 mm wafers and an injector head with several slots for gas-phase reactant delivery, separated by inert N₂ curtains. The reactor is enclosed in a convective oven for temperature control and under atmospheric pressure. The exposure to each reactant is set by the partial pressure of the reactant and the rotation speed expressed in rotations-per-minute (RPM). The injector head is equipped with a dielectric barrier discharge (DBD) plasma source. For the selective deposition of t-TiO₂ and p-TiON, commercially available DMATMS (Gelest) was used without further purification and tested as a small molecule inhibitor. A glass bubbler was filled in a glovebox and kept at room temperature with an Ar bubbling flow of 100 sccm, further diluted with 250 sccm of Ar. DMATMS pretreatments were carried out using 5 substrate rotations underneath the injector head (referred to as 5 “cycles”) at a rotation speed of 50 rpm. Titanium tetrachloride, TiCl₄, was used as the titanium precursor and deionized H₂O as the co-reactant for thermal TiO₂. For plasma TiON, a mixture of N₂ (9900 sccm) and H₂ (100 sccm) was used as a co-reactant, and the plasma was ignited with a dielectric barrier discharge (DBD) plasma source. TiCl₄ was stored in a stainless-steel bubbler and kept at room temperature (vapor pressure 9.6 Torr at 20° C.). An Ar bubbling flow of 25 sccm at a rotation speed of 25 rpm was used to carry the vapor to the injector head. This corresponds to exposure times of ˜100 ms and thus a total exposure of ˜0.03 Torrs. The flow was further diluted with Ar to a total of 1000 sccm before it reached the reactor. Although no oxygen was intentionally added to the plasma-feeding mixtures, background impurities resulted in the incorporation of oxygen. In an earlier study, similar results for SiN that was deposited likewise in the same spatial ALD reactor were reported. Other reports exist on the difficulty of removal of O- and C-impurities from ALD-grown nitride films. In a control experiment, TDMAT was employed as the Ti-precursor and stored in a stainless-steel bubbler and heated to 40° C. (vapor pressure 0.5 Torr at 40° C.). An Ar bubbling flow of 120 sccm at a rotation speed of 25 rpm was used to carry the vapor to the injector head. This corresponds to exposure times of ˜100 ms and a total exposure of ˜0.01 Torrs. H₂O was kept in a glass bubbler at room temperature. An Ar bubbling flow of 250 sccm was further diluted with 750 sccm of Ar, corresponding to total exposure times of ˜0.25 Torrs.

For p-TiON, 100 sccm of H₂ and 9900 sccm of N₂ were supplied to the DBD plasma source which was actuated with a supply voltage of 100 V at a frequency of 75 KHz.

Plasma Etching Process. All etching experiments were performed in the same spatial ALD rotary laboratory-scale reactor. CF₄ and N₂ were transported through separate gas lines to the plasma source from a centralized gas supply and merged only about 50 cm upstream of the plasma source. For the back-etching processes, a flow of 100 sccm was employed for CF₄ and 9900 sccm for N₂ in order to ensure gentle back-etching conditions.

Substrate and Pattern Preparation. ˜80 nm SiN and ˜150 nm SiO₂ layers were deposited on 150 mm c-Si wafers using a PECVD reactor from Elettrorava. The patterned substrates were prepared in a state-of-the-art 300 mm semiconductor fabrication laboratory using lithography, etching, and chemical mechanical polishing to fabricate SiN and SiO₂ line and space patterns.

Analytical Methods. An ex situ Horiba Uvisel 2 spectroscopic ellipsometer was used to measure the thickness of the spatial ALD deposited layers and of the SiO₂ layers before and after each etching experiment. Ellipsometric data were acquired in the range from 1.5 to 3.5 eV with steps of 0.1 eV and 500 ms integration time, and at an incidence angle of 70°, a spot size of 2030×705 μm² and a modulator-analyzer configuration of 0-45°. XPS measurements were performed using a ThermoFisher K-alpha system with a monochromatic Al Kα-radiation and a takeoff angle of 45°. When discussing peak positions, the data were calibrated by referring all spectra to C 1s at 248.8 eV.

Cross-sectional SEM was performed using a Hitachi SU 9000 microscope with an accelerating voltage of 0.5-30 kV, 0.4 nm resolution, and high-quality elemental analysis (EDS).

Cross-sectional TEM was performed in high-angle annular dark-field (HAADF) scanning mode (STEM) and in bright-field TEM modes using a probe-corrected TEM system (JEOL JEM ARM 200F) equipped with a 100 mm² Centurio SDD energy-dispersive X-ray spectroscopy (EDX) detector for chemical analysis. The selectivity, S, from SEM and TEM images was calculated as shown in Equation (1)

$$S = \frac{{X}_{GS} - {X}_{NGS}}{{X}_{GS} + {X}_{NGS}} \qquad ( 1 )$$

wherein X_{GS} and X_{NGS} are measurements of the amount of material deposited on the GS and on the nongrowth surface NGS; for the selectivity in terms of coverage, the area coverage of TiO₂ and TiON islands is calculated for the NGS, while for the selectivity in terms of thickness, the thickness was calculated from the TEM images on NGS and GS.

### RESULTS AND DISCUSSION

Selectivity on Blanket Substrates. The challenging aspect in developing selective deposition processes on SiN as the GS vs. SiO₂ as the NGS is that both materials have similar surface chemistry. This is particularly the case when considering the inevitably present native oxide on the SiN surface, especially when dealing with industrially relevant processes, i.e., half-fabricates consisting of processed-patterned wafers. To this end, an in situ plasma etching step was devised to preclean the SiN from its native oxide and thus achieve a suitable starting surface for further processing.

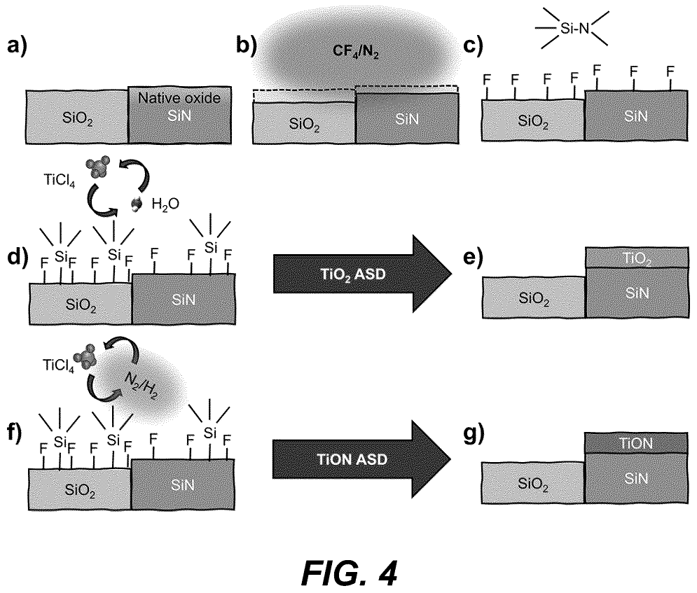

As illustrated in FIG. 4, the entire process consisted of 100 “cycles” of CF₄/N₂ plasma etching to partially remove both SiO₂ and SiN (FIG. 4, panels a and b). Details are available in the Methods section. The etching step was followed by 5 “cycles” of DMATMS as a small molecule inhibitor (SMI; FIG. 4, panel c) for functionalization. Finally, the substrates were exposed to alternating doses of titanium tetrachloride, TiCl₄, and water, for t-TiO₂ AS-ALD (FIG. 4, panels d and e) and alternating doses of TiCl₄ and N₂/H₂ plasma for p-TiON AS-ALD (FIG. 4, panels f and g). A total of 100 and 250 ALD cycles were applied for t-TiO₂ and 250 to 450 cycles for p-TiON.

An atmospheric-pressure dielectric barrier discharge (DBD) plasma process with CF₄/N₂ plasma chemistry was employed as a preconditioning treatment. More details on the plasma etching can be found in Karasulu et al. (2023) Adv. Mater. 35(25), 2301204. 3×3 cm² c-Si substrate coupons with plasma-enhanced chemical vapor deposition (PECVD) SiN and SiO₂ atop were loaded together on a 6 in. stainless-steel substrate holder and subjected to the same processing steps. The resulting samples were analyzed by X-ray photoelectron spectroscopy (XPS) to investigate the nucleation and growth behavior of the respective materials on both the SiO₂ and SiN surfaces. t-TiO₂ was investigated at processing temperatures of 100 and 200° C., respectively, and p-TiON was investigated only at 200° C.

When DMATMS is employed as a pretreatment step only, and not as part of the ALD recipe, are referred to as BC-type cycles, indicating that only TiCl₄ and H₂O are dosed in the ALD step. Conversely, when DMATMS is dosed also as part of the ALD cycle, are referred to as ABC-type cycles.

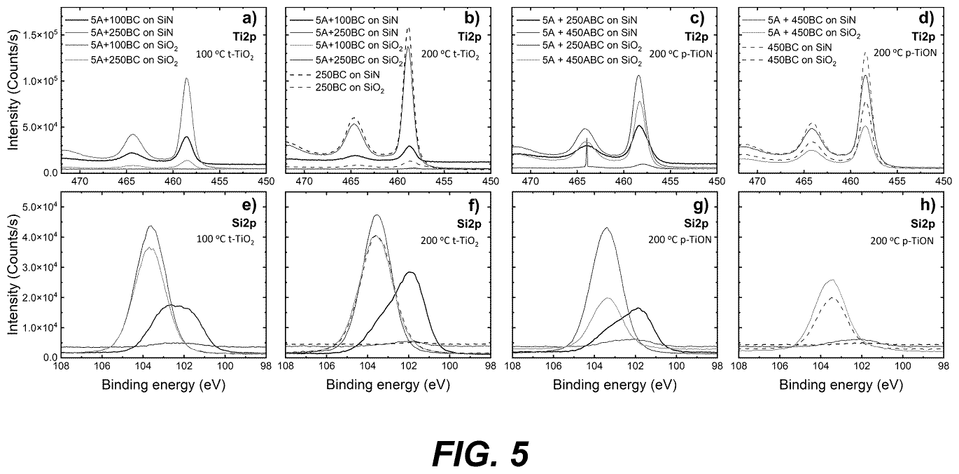

FIG. 5 shows the XPS data for Ti 2p and Si 2p for 100 and 250 ALD cycles of t-TiO₂ and for 250 and 450 ALD cycles of p-TiON on blanket layers of SiN and SiO₂. For t-TiO₂ at 100° C., a significant difference in Ti 2p intensity on SiN vs. SiO₂ was observed, indicating preferential deposition of TiO₂ on SiN vs. SiO₂ (see FIG. 5, panels a and b). After 100 ALD cycles, Ti could not be detected on SiO₂, while Ti 2p features were clearly present on the SiN substrate, thus demonstrating the selective deposition of TiO₂ on SiN vs. SiO₂. After 250 cycles, a minor Ti 2p signal was measured on SiO₂ (loss of selectivity), while concurrent attenuation of the Si 2p peak at ˜104 eV was observed (FIG. 5, panel b), confirming the presence of a TiO₂ overlayer on SiO₂. More intense Ti 2p peaks were instead measured on the SiN substrate, while the Si 2p substrate's features were barely visible, indicating the presence of a thick TiO₂ layer of approximately 10 nm (nominal XPS penetration depth).

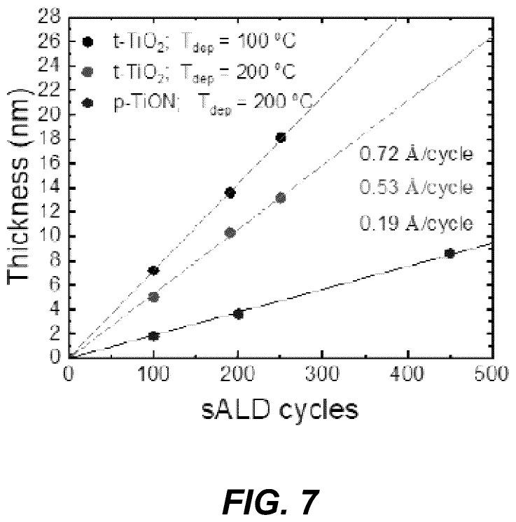

It was noted that, after 100 t-TiO₂ and 250 p-TiON cycles on the SiN substrate, the Si 2p region shows two features: one at ˜102.0 eV, which is consistent with SiN, and one at 103.5 eV which points toward surface oxidation and SiO₂ formation. It is speculated that such oxidation is marginally due to the H₂O dosing and largely due to the fact that the TiO₂ layer is not yet fully closed; thus, postprocess oxidation can easily take place. Using the thickogram method for measuring film thickness (which makes use of the ratio of overlayer and substrate XPS peak intensities together with electron escape depth and sensitivity factors), a nominal TiO₂ thickness of ˜0.7 nm was estimated after 100 cycles on SiN. Based on the growth per cycle (GPC) measurements for the t-TiO₂ process at 100° C. on c-Si substrates, a thickness of ˜7 nm was expected after 100 cycles (see FIG. 7). This observation suggests a significant nucleation delay also on the GS, SiN. Assuming an equal GPC of the standard t-TiO₂ process on c-Si, it is estimated that there is a nucleation delay of ˜70 cycles on the SiN surface. After 250 cycles, a nominal thickness of ˜0.3 nm was calculated from XPS data on the SiO₂ substrate, which indicates a nucleation delay of more than 200 cycles on the NGS.

A consistent behavior was observed also at a deposition temperature of 200° C. for t-TiO₂ as shown in FIG. 5, panels b and f. With respect to the 100° C. case, only a barely visible feature could be observed in the Ti 2p binding energy range after 250 ALD cycles, suggesting an improved selectivity at higher deposition temperatures.

For the case of p-TiON, the water co-reactant was replaced by a remote DBD N₂/H₂ plasma. Two different approaches were tested right after the initial 100 “cycles” CF₄/N₂ plasma etching step, followed by 5 “cycles” of DMATMS surface functionalization (A):
1. (A) DMATMS, (B) TiCl₄, and (C) N₂/H₂ plasma, ABC-type cycles.
2. (B) TiCl₄ and (C) N₂/H₂ plasma, BC-type cycles.

For both ABC-and BC-ALD cycles, preferential deposition of p-TiON on SiN vs. SiO₂ blanket substrates was confirmed by XPS measurements. Compared to the t-TiO₂ case and considering the different GPC values, the obtained selectivity is lower. This is not surprising since selective deposition using plasma-based processes is typically more difficult to achieve because of the high reactivity of plasmas. Based on the thickogram method, after 450 ALD cycles, TiON thicknesses of 7.0 and 7.4 nm were calculated on SiN substrates and ˜1.5 and ˜2.4 nm on SiO₂ were found using ABC- or BC-type recipes, respectively. By considering the uncertainties associated with the thickogram method, it can be concluded that a similar selectivity can be obtained with both ABC-and BC-type methods.

Role of DMATMS on t-TiO₂ and p-TiON Selectivity. To elucidate the influence of DMATMS on the selectivity of BC-type deposition processes, t-TiO₂ and p-TiON deposition runs without DMATMS were carried out, and the resulting samples were analyzed by XPS. FIG. 5, panels b and d compare the Ti 2p signals on SiN and SiO₂ for 250 t-TiO₂ and 450 p-TiON cycles at 200° C. with and without the DMATMS pre-functionalization. In both cases, the XPS data indicate that preferential deposition can be achieved also when skipping the DMATMS functionalization step; i.e., selectivity can be simply obtained by CF₄/N₂ plasma treatment. Comparing the integrated Ti 2p peak areas measured for both cases (with and without DMATMS) reveals that the additional DMATMS step suppresses growth on both GS and NGS, yet to a larger extent on the NGS. These results suggest that DMATMS can still adsorb onto partially etched SiO₂, and, probably to a lower extent, also onto partially etched SiN, which is also in line with literature results (Xu et al. (2022) J. Vac. Sci. Technol. A 40(1), 012403). Based on the ratio of integrated peak areas (which is proportional to the amount of Ti), the effect of the additional DMATMS functionalization is to increase the selectivity of t-TiO₂ by a factor of 10. A consistent yet less pronounced effect was observed for the case of p-TiON, i.e., the insertion of an additional DMATMS functionalization step increases the selectivity by a factor of 1.2 at 450 BC cycles.

The CF₄/N₂ etching pretreatment can, therefore, already confer enough chemical contrast when using TiCl₄ as precursor, while DMATMS intensifies such chemical contrast, thereby leading to increased selectivity.

Selectivity on Patterned Substrates. Effect of Plasma Etching on t-TiO₂. When translating the selective deposition of TiO₂ from blanket layers to patterned substrates, it is crucial to understand and control the CF₄/N₂ pre-deposition etching process. Ideally one needs to remove only the native oxide from the SiN layer.

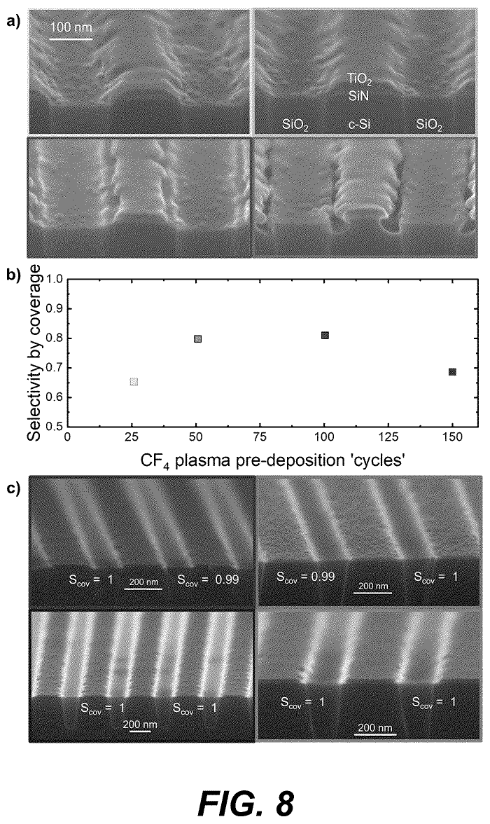

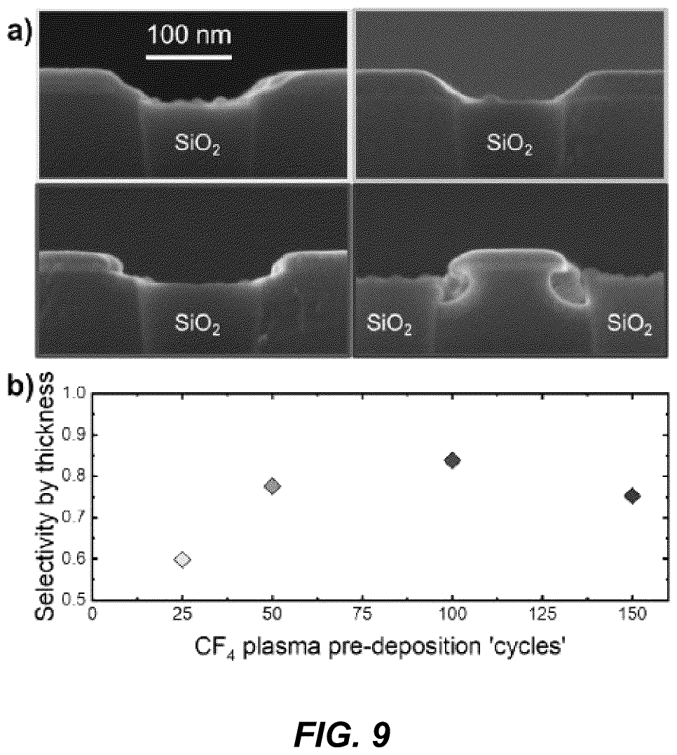

To gain insights into the plasma etching step, 4 different etching pretreatment “cycles” were tested: 25, 50, 100, and 150 CF₄/N₂ “cycles”. The rest of the process was kept the same, i.e. five “cycles” of DMATMS, followed by 250 cycles of t-TiO₂ ALD at 100° C. FIG. 8 shows SEM images in a tilted view, together with the resulting selectivity in terms of coverage (cross-sectional views and selectivity in terms of thickness can be found in FIG. 9). A maximum selectivity of ˜0.8 and 0.85 for coverage and thickness was calculated for a 13 nm TiO₂ layer deposited on SiN, using 100 “cycles” of CF₄/N₂ plasma pretreatment, followed by 5 DMATMS “cycles”. As shown in FIG. 8, panel b, the selectivity was found to be dependent on the overall exposure of the CF₄/N₂ plasma. Although the reaction-mechanical details are not yet known, it is speculated that low cycle numbers may not be sufficient for complete passivation of the SiO₂ surface, while too many may favor redeposition effects and/or formation of defects that can act as nucleation sites and therefore degrade the selectivity. Despite the poor selectivity seen for ˜13 nm t-TiO₂, these results provide several insights into predeposition plasma etching and its effects on selectivity.

Strategies for Improving the Selectivity of t-TiO₂. Several strategies were tested for improving the selectivity of t-TiO₂:
1. decreasing the number of ALD cycles from 250 to 190;
2. keeping 250 ALD cycles followed by a back-etching step to remove unwanted deposition (see FIG. 8, panel c); and
3. increasing the deposition temperature to 200° C., based on the XPS results on blanket substrates.

For all cases, the number of precleaning plasma etching “cycles” prior to deposition was fixed at 50, in order to limit material removal.

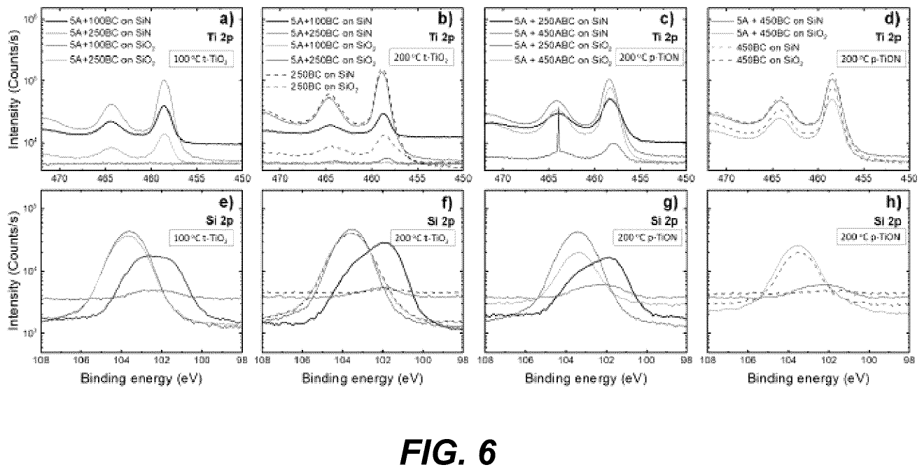

As shown in FIG. 8, panel c and further detailed in Table 1, all of the approaches resulted in improved selectivity. Based on SEM inspection, virtually perfect selectivity could be achieved by deploying CF₄/N₂ back-etching correction steps. Decreasing the number of ALD cycles from 250 to 190 improved the selectivity from 0.80 to 0.99, concurrently the TiO₂ thickness decreased from ˜13 to ˜8 nm. By linear interpolation with a fixed slope equal to the standard GPC, a nucleation delay was found of ˜75 cycles on the SiN, which is consistent with the one estimated from XPS results. Similarly, a nucleation delay of ˜25 cycles can be estimated for TiO₂ at 200° C. on etched and functionalized SiN, assuming the same GPC-value as that measured on c-Si (see FIG. 6).

Fine-tuning either the number of ALD cycles and/or the back-etching “cycles” can potentially lead to larger deposited thicknesses with comparably high selectivity.

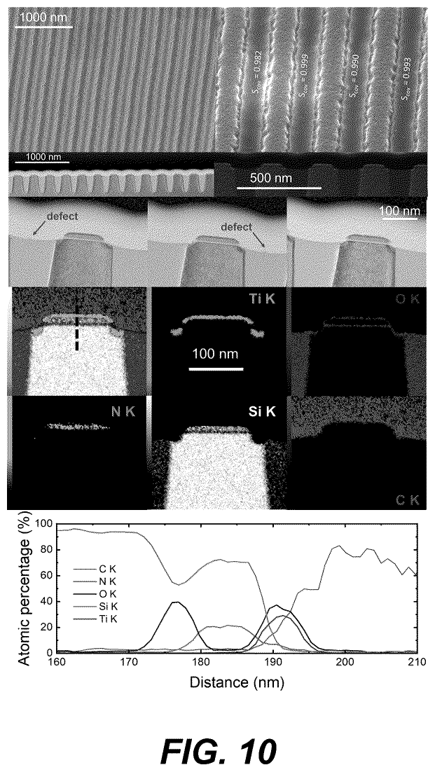

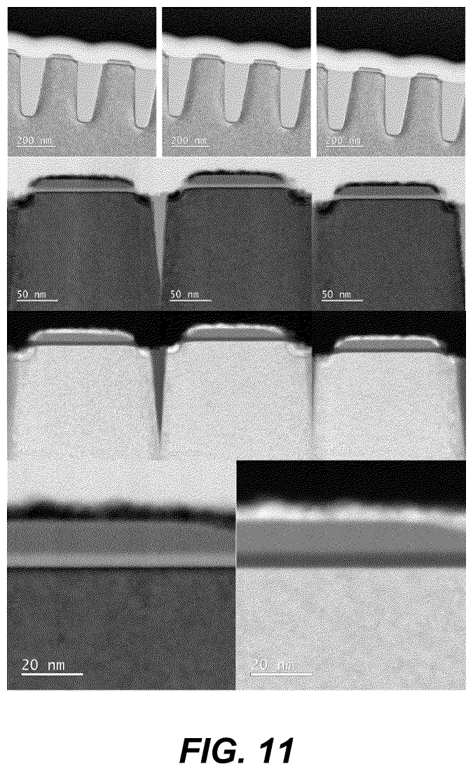

AS-ALD of p-TiON. For p-TiON, 380 BC-type ALD cycles without DMATMS functionalization were selected for tests on patterned substrates since the effect of DMATMS is not so dramatic for the plasma-based process. FIG. 10 shows an overview of SEM and TEM images of the processed sample. From SEM, an averaged selectivity of 0.99 was calculated for a TiON thickness of ˜5 nm, as measured by high-magnification cross-sectional TEM (see FIG. 11). Energy-dispersive X-ray spectroscopy (EDX) measurements performed during cross-sectional TEM further demonstrate the excellent selectivity achieved for p-TiON. The superior potential of this approach is further highlighted by the absence of Ti on the ˜5 nm-thick pad oxide layer that is present between the SiN and the c-Si. This indirectly suggests the scalability of this process to very small pattern pitches, such as the single-digit nanometer scale.

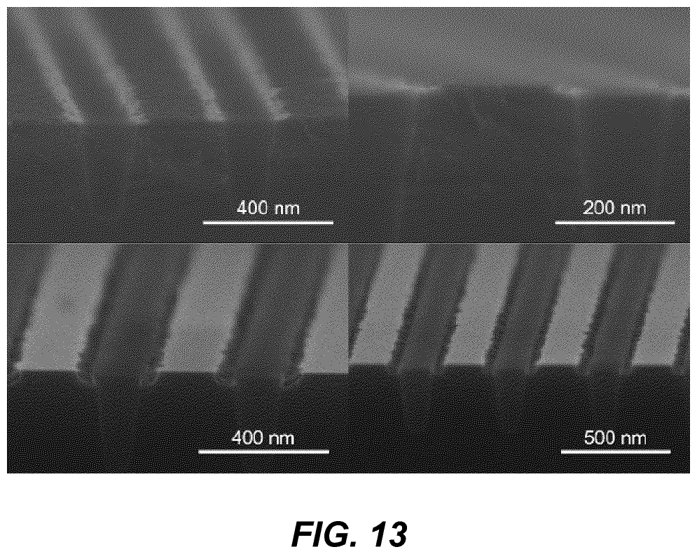

It was noted that an unexpected result was also obtained here: because of the severe lateral overetching of SiN during the pre-deposition plasma etching process c-Si areas became without DMATMS pre-functionalization step and also in line with the XPS observations. Virtually perfect p-TiON selectivity could be obtained when employing back-etching correction steps as shown in FIG. 13.

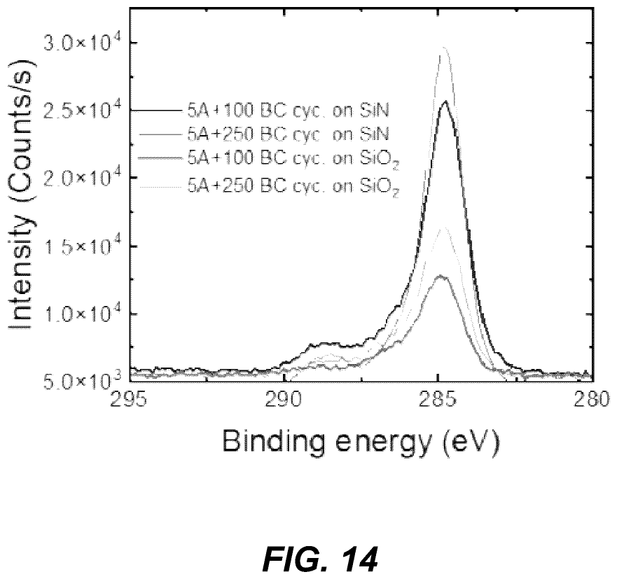

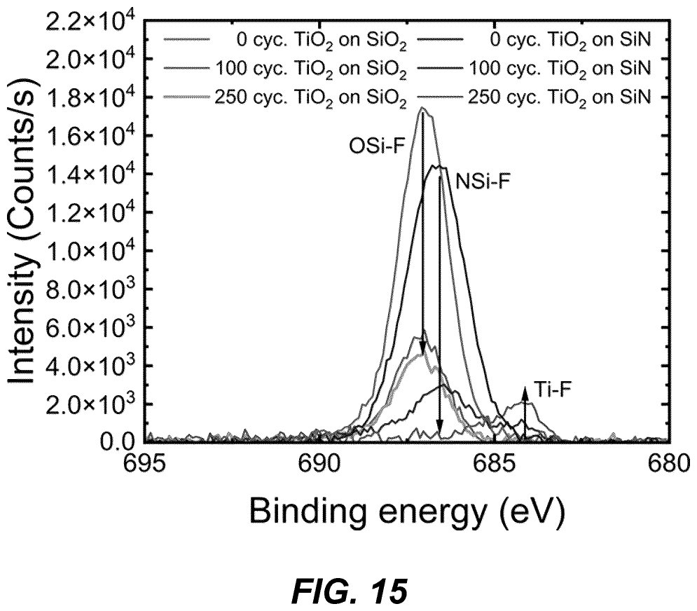

Considerations on Underlying Surface Chemistry and Precursor Effect. XPS data were also employed to gain insights into the surface chemistry underpinning the selective deposition process. The C 1s signal was deconvoluted in three components at 284.8, 286.6, and 288.7 eV. No signals related to CF₂ or CF₃ were detected (see FIG. 14). Contributions from CF species, particularly at low processing temperature, cannot be completely ruled out at this stage; additional data are provided in Table 2, along with related discussion below. The same binding energies for C 1s were also found on a control sample prepared from 250 ALD cycles of standard t-TiO₂ on c-Si. FIG. 15 shows the XPS spectra in the F 1s binding energy range for both SiO₂ and SiN blanket samples, right after the etching step followed by 5 “cycles” of DMATMS (and no cycles of TiO₂) and after additional 100 and 250 ALD cycles of thermal TiO₂ at 100° C. Prior to ALD, a slightly different peak position for the fluorine feature was observed: at 687.0 eV on SiO₂ and 686.7 eV on SiN. The feature at 687 eV can be ascribed to OSi-F bonds, i.e., Si—F bonds on a SiO₂ surface, whereas the one at 686.7 eV can be attributed to NSi-F bonds,24 i.e., Si—F bonds on a SiN surface, and possible CF species. Both features decrease in intensity as the number of ALD cycles increases. This is caused by attenuation due to overlayer thickening as well as F-consumption since no significant deposition takes place on SiO₂ (see FIG. 5, panels a and e). As the number of ALD cycles increases, a new feature centered at 684.2 eV appears on the SiN surface, likely indicating the formation of Ti—F bonds.25 After 250 cycles of TiO₂ the NSi-F/CF feature disappears, while the Ti—F increases in intensity. Based on these few observations, it is believed that such a fluorinated surface layer prevents TiCl₄ from chemisorbing at the surface, due to strong electrostatic repulsion between negatively charged Cl- and F-atoms. This fluorine passivation is gradually removed in favor of the insurgence of Ti—F species as TiO₂ deposition starts to take place. The removal of the fluorinated passivation layer appears to have a higher rate on SiN than on SiO₂, hence the selectivity of the process. Here, density functional theory calculations along with in situ surface analyses would be beneficial in unveiling more details of the underlying chemistry.

Regarding the formation of an interfacial TiOF layer, it is possible that TiCl₄ chemisorbs on exposed NHₓ and OH sites and subsequently forms a bond with neighboring fluorine atoms that are still present at the surface. Here, is where it is believed that DMATMS plays an important role in further improving the selectivity. DMATMS is known to be reactive toward OH-groups. Therefore, it is indicated that DMATMS can passivate exposed OH-groups that are left behind after the plasma etching step and can delay even more the onset of TiCl₄ chemisorption. This is achieved by deactivating exposed OH-groups and forming O—Si (CH₃)₃ surface groups that are nonreactive toward TiCl₄ and H₂O, and possibly by providing an additional steric hindrance.

Effect of Precursor. To further test the hypothesis on the underlying mechanism, similar deposition experiments were performed using tetrakis (dimethylamino) titanium, TDMAT, in place of TiCl₄. From XPS data, some degree of preferential deposition was observed also when employing TOMAT as the Ti-precursor, suggesting a broader applicability of the selective deposition method. However, the selectivity is only marginal compared to the CI-based precursor process, which indicates that electrostatic repulsion between the fluorinated surface and the chlorinated precursor is the underlying chemical principle for excellent selectivity.

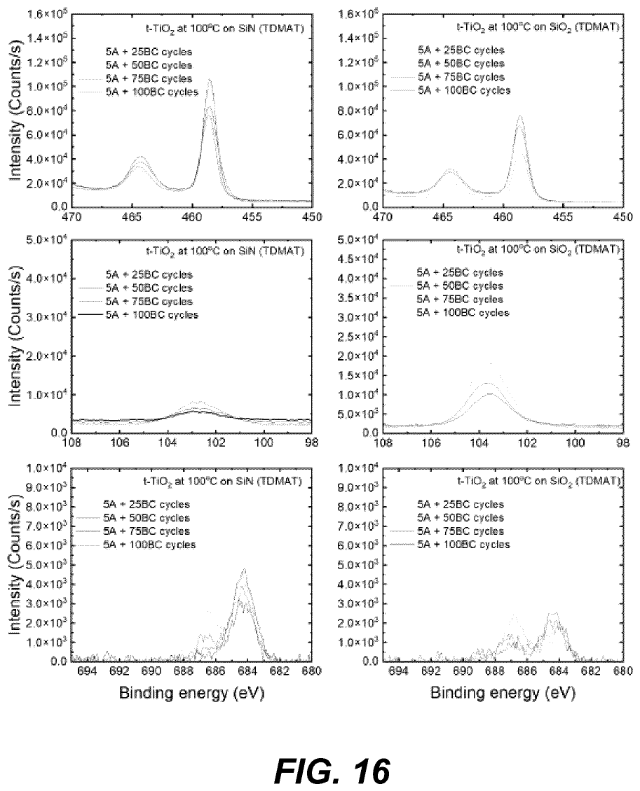

Testing the same approach with TOMAT as for the titanium precursor provided a few additional insights. FIG. 16 shows the XPS data indicating preferential deposition of TiO₂ on SiN vs. SiO₂ also when using TDMAT and H₂O at 100° C. After 100 cycles, TiO₂ thicknesses of ˜8.0 and ˜3.5 nm were estimated on SiN and SiO₂, respectively, using the thickogram method. Indicating the potential for achieving ˜4.5 nm selective deposition of TiO₂ when using TDMAT as the titanium precursor. Comparing the integrated Ti 2p peak area for TDMAT with the ones obtained for TiCl₄, it is noted that deposition is less delayed on both SiN and SiO₂ surfaces for TDMAT. Also, on the samples deposited using TDMAT, it is noted that the presence of OSi-F and NSi-F features, together with the formation of Ti-F bond signals on both SiO₂ and SiN. These data thus indicate that deposition starts through the formation of a TiOF interlayer and then proceeds to form TiO₂.

Table 2 provides an overview of layer composition from XPS surface scans, together with processing conditions. Whilst it is currently not possible to rule out the presence of CF species at the interface, it is noted that a comparable level of C at. % is found on SiN and for a standard ALD process on c-Si. Without plasma pre-treatment and inhibitor a C percentage of 14 at. % is found after 250 cycles on c-Si both at 100 and 200° C. This is likely due to adventitious carbon. For CF4 plasma-treated SiN, followed by 250 ALD cycles of TiO₂ at 200° C., both with and without additional inhibitor functionalization, similar carbon percentages of 16.2 and 10.7 at. % were found. Furthermore, only a minor F at. % is measured on these samples. These results therefore suggest similar C-content levels on c-Si and SiN. On the other hand, the same experimental conditions on SiO₂ lead to a much lower carbon content. However, almost no Ti is present on these surfaces, and it is therefore likely that the fluorine at the surface affects the carbon uptake from the atmosphere.

At 100° C., an unexpectedly high carbon content was found on SiN, 28.1 at. %, while only 9.7% was found on SiO₂. It therefore can be concluded that at low processing temperatures CF species may play a mediating role in the selectivity of TiO₂ growth on SiN vs. SiO₂.

### Conclusions

ASD of TiO₂ and TiON on SiN vs. SiO₂ has been demonstrated for the first time by using atmospheric-pressure spatial ALD on industrially processed patterns. The process exploits the chemical affinity contrast provided by a pre-deposition CF₄/N₂ etching step and the electrostatic repulsion between TiCl₄ and the partially fluorinated SiN and SiO₂ surfaces. Such a chemical contrast can be further enhanced by adding an additional DMATMS functionalization step. Through SEM inspection, AS-ALD of ˜8 and ˜7 nm-thick TiO₂ on SiN vs. SiO₂ with a selectivity of 0.99 and 1.00 for 190 ALD cycles at processing temperatures of 100 and 200° C., and AS-ALD of ˜5 nm TiON on SiN vs. SiO₂ with a selectivity of 0.99 at processing temperatures of 200° C. have been seen.

The selectivity can further be improved by increasing the number of ALD cycles and combining it with back-etching steps to remove unwanted defects. The latter approach resulted in virtually perfect selectivity, i.e., no observable spurious particles on the SiO₂ patterns.

A few considerations about the possible mechanistic aspects of the selective process can be derived from these results. The different fluorine binding configurations on SiN vs. SiO₂ stand out as the possible main driver for the selectivity of the process. TDMAT was tested as an alternative titanium precursor, and it was determined that for TDMAT a much lower selectivity (<5 nm) was obtained. While the difference between TDMAT and TiCl4 may be due to differences in size, reactivity, and available reaction pathways, the comparison supports the concept of electrostatic repulsion as a mechanism behind the high selectivity obtained with TiCl₄. The underlying chemistry underpinning the selectivity may lead to novel precursors and process designs for achieving ASD targeting SiN vs. SiO₂ surfaces.

The results presented herein add to the fundamental understanding of and lead to new concepts and approaches for ASD applications.

TABLE 1
SEM-Measured Thickness and Averaged Selectivity for Different TiO₂
AS-ALD Approaches^{a}

| | | processing | | averaged |
|---|---|---|---|---|
| number of | number of back- | temperature | thickness | selectivity from |
| ALD cycles | etching “cycles” | (° C.) | (nm) | SEM coverage |
| 190 | 0 | 100 | ~8 | 0.99 |
| 250 | 0 | 100 | ~13 | 0.80 |
| 250 | 80 | 100 | ~8 | 1.00 |
| 190 | 0 | 200 | ~8 | 1.00 |
| 250 | 20 | 200 | ~7 | 1.00 |

ªThe pre-deposition etching step was fixed to 50 “cycles” of CF₄/N₂ plasma.

TABLE 2
XPS atomic percentage from surface scans, together with processing conditions and initial substrate surfaces.

| | | CF₄ | | | | | | | | | |
|---|---|---|---|---|---|---|---|---|---|---|---|
| Processing | | plasma | DMATMS | Thermal | Composition | | | | | | |
| temperature | | treatment | functionalization | ALD | Ti | O | C | Si | F | Cl | N |
| (° C.) | Substrate | “cycles” | cycles | cycles | (at. %) | (at. %) | (at. %) | (at. %) | (at. %) | (at. %) | (at. %) |
| 200 | SiO₂ | 100 | 5 | 250 | 0.2 | 63.9 | 2.2 | 30.5 | 2.6 | 0.2 | 0.4 |
| | SiN | 100 | 5 | 250 | 22.5 | 55.5 | 16.2 | 2.1 | 0.5 | 0.5 | 2.7 |
| | c-Si | 0 | 0 | 250 | 25.7 | 58.8 | 14.0 | 0.7 | 0.0 | 0.3 | 0.4 |
| | SiO₂ | 100 | 0 | 250 | 1.7 | 64.3 | 2.0 | 29.6 | 2.0 | 0.2 | 0.2 |
| | SiN | 100 | 0 | 250 | 26.6 | 60.7 | 10.7 | 0.6 | 0.4 | 0.4 | 0.7 |
| 100 | SiO₂ | 100 | 5 | 250 | 1.5 | 59.9 | 9.7 | 26.9 | 1.2 | 0.2 | 0.4 |
| | SiN | 100 | 5 | 250 | 18.5 | 47.1 | 28.1 | 2.3 | 1.0 | 0.7 | 2.4 |
| | c-Si | 0 | 0 | 250 | 25.9 | 58.7 | 14.0 | 0.0 | 0.0 | 1.0 | 0.5 |

### REFERENCES

(1) Nguyen, C. T.; Cho, E. H.; Gu, B.; Lee, S.; Kim, H. S.; Park, J.; Yu, N. K.; Shin, S.; Shong, B.; Lee, J. Y.; Lee, H. B. R. Gradient Area-Selective Deposition for Seamless Gap-Filling in 3D Nanostructures through Surface Chemical Reactivity Control. Nat. Commun. 2022, 13(1), 7597.

(2) Parsons, G. N.; Clark, R. D. Area-Selective Deposition: Fundamentals, Applications, and Future Outlook. Chem. Mater. 2020, 32(12), 4920-4953.

(3) Chen, H. P.; Wu, Y. H.; Huang, H. Y.; Tsai, C. H.; Lee, S. K.; Lee, C. C.; Wei, T. H.; Yao, H. C.; Wang, Y. C.; Liao, C. Y.; Chang, H. K.; Lu, C. W.; Shue, W. S.; Cao, M. Fully Self-Aligned Via Integration for Interconnect Scaling beyond 3nm Node; 2021 IEEE International Electron Devices Meeting (IEDM); IEEE, 2021, pp. 22.1.1-22.1.4. DOI:.

(4) Murdoch, G.; Bommels, J.; Wilson, C. J.; Gavan, K. B.; Le, Q. T.; Tokei, Z.; Clark, W. Feasibility Study of Fully Self Aligned Vias for 5 nm Node BEOL; 2017 IEEE International Interconnect Technology Conference (IITC); IEEE, 2017, pp. 10-13, DOI:.

(5) Hughes, K. J.; Engstrom, J. R. Nucleation Delay in Atomic Layer Deposition on a Thin Organic Layer and the Role of Reaction Thermochemistry. J. Vac. Sci. Technol. A Vacuum, Surfaces, Film. 2012, 30(1), No. 01A102.

(6) Johnson, R. W.; Hultqvist, A.; Bent, S. F. A Brief Review of Atomic Layer Deposition: From Fundamentals to Applications. Mater. Today 2014, 17(5), 236-246.

(7) Mårtensson, P.; Carlsson, J.-O. Atomic Layer Epitaxy of Copper: Growth and Selectivity in the Cu(II)-2,2,6,6-tetramethyl-3,5-heptanedionate/Process. J. Electrochem. Soc. 1998, 145(8), 2926-2931.

(8) Mameli, A.; Kuang, Y.; Aghaee, M.; Ande, C. K.; Karasulu, B.; Creatore, M.; Mackus, A. J. M.; Kessels, W. M. M.; Roozeboom, F. Area-Selective Atomic Layer Deposition of In₂O₃: H Using a μ-Plasma Printer for Local Area Activation. Chem. Mater. 2017, 29, 921-925.

(9) Suh, T.; Yang, Y.; Sohn, H. W.; DiStasio, R. A.; Engstrom, J. R. Area-Selective Atomic Layer Deposition Enabled by Competitive Adsorption. J. Vac. Sci. Technol. A Vacuum, Surfaces, Film. 2020, 38(6), No. 062411.

(10) Atanasov, S. E.; Kalanyan, B.; Parsons, G. N. Inherent Substrate-Dependent Growth Initiation and Selective-Area Atomic Layer Deposition of TiO₂ Using “Water-Free” Metal-Halide/Metal Alkoxide Reactants. J. Vac. Sci. Technol. A Vacuum, Surfaces, Film. 2016, 34(1), No. 01A148.

(11) Kalanyan, B.; Lemaire, P. C.; Atanasov, S. E.; Ritz, M. J.; Parsons, G. N. Using Hydrogen to Expand the Inherent Substrate Selectivity Window during Tungsten Atomic Layer Deposition. Chem. Mater. 2016, 28(1), 117-126.

(12) Mameli, A.; Teplyakov, A. V. Selection Criteria for Small-Molecule Inhibitors in Area-Selective Atomic Layer Deposition: Fundamental Surface Chemistry Considerations. Acc. Chem. Res. 2023, 56(15), 2084-2095.

(13) Zyulkov, I.; Krishtab, M.; DeGendt, S.; Armini, S. Selective Ru ALD as a Catalyst for Sub-Seven-Nanometer Bottom-Up Metal Interconnects. ACS Appl. Mater. Interfaces 2017, 9(36), 31031-31041.

(14) Soethoudt, J.; Tomczak, Y.; Meynaerts, B.; Chan, B. T.; Delabie, A. Insight into Selective Surface Reactions of Dimethylamino-Trimethylsilane for Area-Selective Deposition of Metal, Nitride, and Oxide. J. Phys. Chem. C 2020, 124(13), 7163-7173.

(15) Bobb-Semple, D.; Nardi, K. L.; Draeger, N.; Hausmann, D. M.; Bent, S. F. Area-Selective Atomic Layer Deposition Assisted by Self-Assembled Monolayers: A Comparison of Cu, Co, W, and Ru. Chem. Mater. 2019, 31(5), 1635-1645.

(16) Xu, W.; Gasvoda, R. J.; Lemaire, P. C.; Sharma, K.; Hausmann, D. M.; Agarwal, S. Area-Selective Atomic Layer Deposition of Al₂O₃ on SiNₓ with SiO₂ as the Nongrowth Surface. J.Vac. Sci. Technol. A 2022, 40(1), No. 012403.

(17) Bergström, L. Surface Chemistry of Silicon Nitride Powders: Adsorption from Non-Aqueous Solutions. Colloids Surf. 1992, 69(1), 53-64.

(18) Karasulu, B.; Roozeboom, F.; Mameli, A. High-Throughput Area-Selective Spatial Atomic Layer Deposition of SiO₂ with Interleaved Small Molecule Inhibitors and Integrated Back-Etch Correction for Low Defectivity. Adv. Mater. 2023, 35(25), No. 2301204.

(19) Mameli, A.; Merkx, M. J. M.; Karasulu, B.; Roozeboom, F.; Kessels, W. M. M.; Mackus, A. J. M. Area-Selective Atomic Layer Deposition of SiO₂ Using Acetylacetone as a Chemoselective Inhibitor in an ABC-Type Cycle. ACS Nano 2017, 11(9), 9303-9311.

(20) Cumpson, P. J.; Zalm, P. C. Thickogram: A Method for Easy Film Thickness Measurement in XPS. Surf. Interface Anal. 2000, 29(6), 403-406.

(21) Hyungjun, K.; Han-Bo-Ram, L.; Woo-hHee, K.; Jeong won, L.; Jaemin, K.; Inchan, H. The Degradation of Deposition Blocking Layer during Area Selective Plasma Enhanced Atomic Layer Deposition of Cobalt. J. Korean Phys. Soc. 2010, 56(1), 104.

(22) Metzler, D.; Bruce, R. L.; Engelmann, S.; Joseph, E. A.; Oehrlein, G. S. Fluorocarbon Assisted Atomic Layer Etching of SiO₂ Using Cyclic Ar/C₄F₈ Plasma. J. Vac. Sci. Technol. A Vacuum, Surfaces, Film. 2014, 32(2), No. 020603.

(23) Gasvoda, R. J.; Zhang, Z.; Wang, S.; Hudson, E. A.; Agarwal, S. Etch Selectivity during Plasma-Assisted Etching of SiO₂ and SiNₓ: Transitioning from Reactive lon Etching to Atomic Layer Etching. J. Vac. Sci. Technol. A Vacuum, Surfaces, Film. 2020, 38(5), No. 050803.

(24) Brunet, M.; Aureau, D.; Chantraine, P.; Guillemot, F.; Etcheberry, A.; Gouget-Iaemmel, A. C.; Ozanam, F. Etching and Chemical Control of the Silicon Nitride Surface. ACS Appl. Mater. Interfaces 2017, 9(3), 3075-3084.

(25) Nirmal, K. A.; Ren, W.; Khot, A. C.; Kang, D. Y.; Dongale, T. D.; Kim, T. G. Flexible Memristive Organic Solar Cell Using Multilayer 2D Titanium Carbide MXene Electrodes. Adv. Sci. 2023, 10(19), 1-10.

(26) Khan, R.; Shong, B.; Ko, B. G.; Lee, J. K.; Lee, H.; Park, J. Y.; Oh, I. K.; Raya, S. S.; Hong, H. M.; Chung, K. B.; Luber, E. J.; Kim, Y. S.; Lee, C. H.; Kim, W. H.; Lee, H. B. R. Area-Selective Atomic Layer Deposition Using Si Precursors as Inhibitors. Chem. Mater. 2018, 30(21), 7603-7610.

(27) Illiberi, A.; Scherpenborg, R.; Roozeboom, F.; Poodt, P. Atmospheric Spatial Atomic Layer Deposition of In-Doped ZnO. ECS J. Solid State Sci. Technol. 2014, 3(5), P111-P114.

(28) Shen, J.; Roozeboom, F.; Mameli, A. Atmospheric-Pressure Plasma-Enhanced Spatial Atomic Layer Deposition of Silicon Nitride at Low Temperature. At. Layer Depos. 2023, 1, 1-11.

(29) Karwal, S.; Verheijen, M. A.; Arts, K.; Faraz, T.; Kessels, W. M. M.; Creatore, M. Plasma-Assisted ALD of Highly Conductive HfNₓ: On the Effect of Energetic Ions on Film Microstructure. Plasma Chem. Plasma Process. 2020, 40(3), 697-712.

(30) Karwal, S.; Karasulu, B.; Knoops, H. C. M.; Vandalon, V.; Kessels, W. M. M.; Creatore, M. Atomic Insights into the Oxygen Incorporation in Atomic Layer Deposited Conductive Nitrides and Its Mitigation by Energetic lons. Nanoscale 2021, 13(22), 10092-10099.

(31) Knoops, H. C. M.; De Peuter, K.; Kessels, W. M. M. Redeposition in Plasma-Assisted Atomic Layer Deposition: Silicon Nitride Film Quality Ruled by the Gas Residence Time. Appl. Phys. Lett. 2015, 107(1), 014102.

(32) Knoops, H. C. M.; Braeken, E. M. J.; De Peuter, K.; Potts, S. E.; Haukka, S.; Pore, V.; Kessels, W. M. M. Atomic Layer Deposition of Silicon Nitride from Bis(Tert-Butylamino)Silane and N₂ Plasma. ACS Appl. Mater. Interfaces 2015, 7(35), 19857-19862.

(33) Gladfelter, W. L. Selective Metallization by Chemical Vapor Deposition. Chem. Mater. 1993, 5(10), 1372-1388.

Although the foregoing subject matter has been described in some detail by way of illustrations and examples for purposes of clarity of understanding, it will be understood by those skilled in the art that certain changes and modifications can be practiced within the scope of the appended claims.

That which is claimed:

1. A method of selectively depositing a metal oxide or metal oxynitride on a substrate, the substrate comprising a surface, the surface comprising: an oxide layer portion comprising hydroxyl groups on SiO₂ and a nitride layer portion, the method comprising:
pretreating the surface with a plasma, wherein the plasma removes a native oxide layer on the nitride layer portion; and
functionalizing the surface of the substrate with at least one cycle of exposing the surface to an aminosilane small molecule inhibitor,
followed by at least one cycle of:
exposing the surface to a metal precursor; and
exposing the surface to a co-reactant,
to provide a metal oxide or metal oxynitride layer selectively deposited on the nitride layer portion of the substrate over the oxide layer portion of the substrate.

2. The method of claim 1, wherein the nitride layer portion of the substrate comprises silicon nitride (SiN).

3. The method of claim 1, wherein the plasma for pretreating the surface comprises a CF₄/N₂ plasma.

4. The method of claim 1, wherein the small molecule inhibitor is bis-(dimethylamino)dimethylsilane (BDMADMS) or (dimethylamino)trimethylsilane (DMATMS).

5. The method of claim 1, wherein the metal precursor comprises titanium (Ti).

6. The method of claim 5, wherein the metal precursor is TiCl₄.

7. The method of claim 1, wherein the co-reactant comprises H₂O or an N₂/H₂ plasma.

8. The method of claim 1, wherein the method further comprises back-etching the surface with a plasma following the at least one cycle or cycles of exposing the surface to a metal precursor and co-reactant.

9. The method of claim 9, wherein the plasma for back-etching the surface comprises a CF₄/N₂ plasma.

10. The method of claim 1, wherein deposition on the nitride layer portion over the oxide layer portion has a selectivity S of about 0.99-1.00.

11. A method of selectively depositing a metal oxide or metal oxynitride on a substrate, the substrate comprising a surface, the surface comprising: an oxide layer portion comprising hydroxyl groups on SiO₂ and a nitride layer portion, the method comprising:
pretreating the surface with a plasma, wherein the plasma removes a native oxide layer on the nitride layer portion; and
at least one cycle of:
functionalizing the surface of the substrate by exposing the surface to an aminosilane small molecule inhibitor;
exposing the surface to a metal precursor; and
exposing the surface to a co-reactant,
to provide a metal oxide or metal oxynitride layer selectively deposited on the nitride layer portion of the substrate over the oxide layer portion of the substrate.

12. The method of claim 11, wherein the nitride layer portion of the substrate comprises silicon nitride (SiN).

13. The method of claim 11, wherein the plasma for pretreating the surface comprises a CF₄/N₂ plasma.

14. The method of claim 11, wherein the aminosilane small molecule inhibitor is bis-(dimethylamino)dimethylsilane (BDMADMS) or (dimethylamino)trimethylsilane (DMATMS).

15. The method of claim 11, wherein the metal precursor comprises titanium (Ti).

16. The method of claim 15, wherein metal precursor is TiCl₄.

17. The method of claim 11, wherein the co-reactant comprises H₂O or an N₂/H₂ plasma.

18. The method of claim 11, wherein the method further comprises back-etching the surface with a plasma following the at least one cycle or cycles of functionalizing the surface and exposing the surface to a metal precursor and co-reactant.

19. The method of claim 19, wherein the plasma for back-etching the surface comprises a CF₄/N₂ plasma.

20. The method of claim 1, wherein deposition on the nitride layer portion over the oxide layer portion has a selectivity S of about 0.99-1.00.

21. A tool for performing the method of claim 1.

22. A patterned layer prepared by the method of claim 1.
